(19) United States
(12) Patent Application Publication
(10) Pub. No.: US 2019/0123742 A1
(43) Pub. Date: Apr. 25, 2019

(54) MULTIFUNCTION TERMINALS FOR ALARM SYSTEMS

(71) Applicant: Keith Michael Konheim, Santa Barbara, CA (US)

(72) Inventor: Keith Michael Konheim, Santa Barbara, CA (US)

(73) Assignee: Keith Michael Konheim, Santa Barbara, CA (US)

(21) Appl. No.: 16/164,857

(22) Filed: Oct. 19, 2018

Related U.S. Application Data
(60) Provisional application No. 62/574,320, filed on Oct. 19, 2017.

(51) Int. Cl. H03K 17/687; G08B 13/22

(52) U.S. Cl. CPC H03K 17/6872; G08B 13/22

(57) ABSTRACT

New in the art to which this invention pertains is the ability to configure an Output Terminal through software with hardware connected to such output terminal which can perform Multiple Functions. The Functions that this circuit can be configured through software are as follows but not limited to Analog Voltage Measurements, Data Transmission or Data Receiving, Solenoid driving either through sinking or sourcing current, Speaker/Siren Driving.

### BACKGROUND OF THE INVENTION

Alarm systems have evolved to perform many added functions besides detecting a door in the open or closed position. Presently the design used is to assign a specific terminal to specific functions, such as electronic devices to unlock a door, data keypads or other user interfaces or analog voltage measurement for the industry standard of an End of Line Resistor to detect door and window closure.

If additional terminals for doors are needed beyond what is available on the circuit board, a second board must be connected. These additional connection boards are also specific to the number and type of applications. For instance most data for Keypads or entry or exit access is transmitted on a bus (Multiple Keypads can share a single bus on some systems) using one end of a differential driver IC. The terminal connected to this IC can only perform one function, that of data transmission or receiving.

The purpose of my invention is to be able to use, but not limited to devices such as Keypads, Frequency Operated Button, Electronic Key, Card Readers, Door Lock Solenoids, End of Line resistance measurements used in Alarm Systems, but not limited to Alarm Systems such as a sprinkler controller, connected to a terminal and configured by software through specific bits attached to the terminal circuit.

### SUMMARY OF THE INVENTION

My invention is a circuit that improves Alarm systems by adding the flexibility through software to configure an output terminal for typical device functions of Alarm System Devices. With a number of these circuits on a single Circuit Board, installers can use fewer different Circuit Boards.

### BRIEF DESCRIPTION OF THE VIEWS OF THE INVENTION

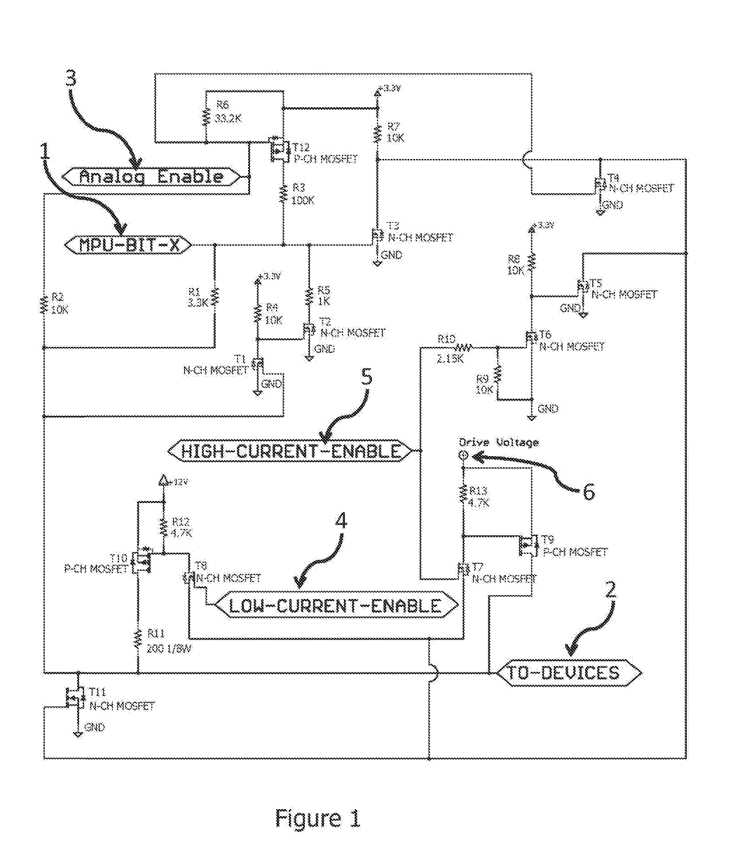

FIG. 1 depicts the Schematic of the Invention.

### DETAILED DESCRIPTION OF THE INVENTION

The detailed description set forth below in connection with the appended drawing is intended as a description of presently-preferred embodiments of the invention and is not intended to represent the only forms in which the present invention may be constructed or utilized. The description sets forth the functions and the sequence of steps for constructing and operating the invention in connection with the illustrated embodiments. It is to be understood, however, that the same or equivalent functions and sequences may be accomplished by different embodiments that are also intended to be encompassed within the spirit and scope of the invention. This invention is a circuit that enables terminals on an Alarm System perform multiple functions.

One of the functions is data communication with data entry ‘Keypads’. This invention allows an Alarm System to communicate with keypads that use various voltage levels on their communication lines (between Alarm system and keypad)

Another function this invention enables is operating a solenoid or other electronic device to electronically control a mechanism that unlocks a door.

Another function these Terminals can perform is to measure resistance in a line typically used on sensors for windows and doors that indicate they are closed

Another function these Terminals can perform is to drive a speaker.

Another function this circuit can perform is to output a standard 24 VAC to control a sprinkler valve, but for this function 2 Terminals must be used The frequency and or voltage is not limited to 24 Volts or 50 or 60 Hertz.

### BEST MODE OF THE INVENTION

The operation of this circuit according to FIG. 1 is as follows:

Connections are made as follows: A Typical bit from a typical MPU capable of A/D measurements plus outputting binary numbers at a 3.3 Volt Logic Level is connected to ‘1’. A second bit, for enabling typical Alarm System Analog measurements is connected to ‘3’. A third bit, at the typical 3.3 Volt Binary Output is connected is connected to ‘4’, to enable the output of a current limited signal, where a high current would damage External Devices. A fourth bit, at the typical 3.3 Volt Binary Output is connected is connected to ‘5’. A Voltage source is connected to ‘6’. The output terminal is connected to ‘2’

In the Analog measurement mode, the bit connected to ‘1’ on the MPU is configured with software to measure Analog Voltages. ‘3’ is set high, ‘4’ & ‘5’ are set Low. The voltage at ‘6’ is N/A. The resistance connected between ‘2’ and Ground as is typical of End of Line Resistors creates a Voltage at ‘2’ which goes through R1. For instance if an EOL Resistance of 1.8K is used, there will be a voltage of 0.5 Volts. This is not enough for the Gate at T1, so T1 remains off and T2 is on adding R5 to Ground. The Voltage is R1/R5 with the source voltage R2/EOL resistor. A Voltage source placed at ‘2’ in place of the resistor can be detected by setting the bit connected to ‘3’ to either Ground or a Logic input. When set the bit connected to ‘3’ is set to an Input, R2 will ‘Float’. With the bit connected to ‘3’ set to Ground, R2 is in parallel with the EOL Resistor plus the Value of R1 as a Voltage divider with R3 pulled up to a Logic High by T12.

In the Data Receive mode, the bit connected to ‘1’ on the MPU is configured to an Input. The bit connected to ‘3’ on the MPU is configured to output a ‘Low’ grounding the gate at T12 thus turning on the P Channel MOSFET. When a ‘High’ signal is placed at ‘2’, and the high signal can be anything from the max Gate to Source rating to turn on T1 to the Maximum voltage rating for T1, Gate to Drain, T1 conducts. This then turns off T2 and the voltage at ‘1’ is pulled through R3 and T12 to 3.3 Volts. When a ‘Low’ signal is placed at ‘2’, T1 is off turning on T2 which provides a Logic Low at ‘1’.

In the data transmit or drive mode, the bit connected to ‘1’ on the MPU is configured to an output. ‘3’ is an Output set at a logic ‘Low’, disabling T4 which enables the Gate of T11 to be pulled ‘High’. Outputting a current limited voltage, A logic ‘High’ is set on both ‘1’ and ‘4’. With ‘4’ remaining ‘High’, ‘5’ is set ‘Low’. When ‘1’ is ‘High’ with a corresponding ‘High’ on ‘4’, T3 provides the Ground for T8, Turning on T10 which provides the Voltage at the Source of T10 through R11 to ‘2’. When T8 has a path to ground on the Source, this also Grounds the Gate of T11, keeping this MOSFET in the off state. A ‘Low’ at ‘1’ will turn T10 off, without turning T11 on.

In the data transmit or drive mode where a true output ‘Low’ at ‘2’ is pulled to ground, the bit connected to ‘1’ on the MPU is configured to an output. ‘3’ is an Output set at logic ‘Low’, disabling T4 which enables the Gate of T11 to be pulled ‘High’. Outputting a ‘Low’ on ‘1’ and a ‘High’ on ‘5’ turns on T11, sinking or pulling the Voltage at ‘2’ to Ground. The gate of T6 ‘High’ turns off T5, enabling R7 to pull the Gate of T11 High turning T11 ‘On’ sinking ‘2’ to ground.

In the data transmit or drive mode where a non-current limited output at ‘2’ is required, ‘Outputting a ‘High’ on ‘1’ and a ‘High’ on ‘5’ will turn on T9 by providing a ‘Low’ at the Gate of T9 through T7. This also grounds the Gate of T11, keeping this MOSFET in the off state. This will place the voltage at ‘6’, on ‘2’ through T9. When T7 has a path to ground on the Source from T3, this also Grounds the Gate of T11, keeping this MOSFET in the off state. The voltage at ‘2’ can be controlled with Pulse Width Modulation at ‘5’. With a Voltage such as 34 Volts at ‘6’, a sine wave for 24 Volts can be generated at a frequency such as 60 or 50 Hertz with PWM on ‘5’. This is not limited to these lower frequencies as another common frequency is 400 Hz. For Alternating Current, two such circuits are used alternating between Sinking and Driving at ‘2’, at the frequency and Voltage required. PWM is a standard method of converting a high voltage into a lower voltage. Any Voltage lower than that at ‘6’ such as 12 Volts or 5 Volts or 3.3 Volts can be generated with the proper PWM signal on ‘5’.

What is claimed is:

1. The Multifunction Terminals For Alarm Systems comprising the circuit in FIG. 1, with elements/methods/processes described above, is a circuit used for multiple purposes such as Data Transmission or Data Receiving or Variable Voltage Output including generation of Sine Waves or Audio Output through a Speaker/Siren Driving, but not limited to the features described, that can be configured through software.
